(19) United States
(12) Patent Application Publication
(10) Pub. No.: US 2022/0149229 A1
(43) Pub. Date: May 12, 2022

(54) MIXED STRAIN MULTI-QUANTUM WELL SUPERLUMINESCENT LIGHT EMITTING DIODE

(71) Applicant: DENSELIGHT SEMICONDUCTORS PTE LTD, Singapore (SG)

(72) Inventors: Royston Hogan, Singapore (SG); Andy Piper, Singapore (SG); Rajan Rajgopal, Singapore (SG); Ashish Kumar Rai, Singapore (SG); Dasa Lakshmi Narayana Dheeraj, Singapore (SG)

(73) Assignee: DENSELIGHT SEMICONDUCTORS PTE LTD, Singapore (SG)

(21) Appl. No.: 17/454,722

(22) Filed: Nov. 12, 2021

Related U.S. Application Data
(60) Provisional application No. 63/112,905, filed on Nov. 12, 2020.
(60) Provisional application No. 63/169,192, filed on Mar. 31, 2021.
(60) Provisional application No. 63/173,764, filed on Apr. 12, 2021.
(60) Provisional application No. 63/243,385, filed on Sep. 13, 2021.

(51) Int. Cl. H01L 33/00; H01L 33/06; H01L 33/12

(52) U.S. Cl. CPC H01L 33/0045; H01L 33/12; H01L 33/06

(57) ABSTRACT

A superluminescent light emitting diode (SLED) includes an active layer that includes a set of mixed strain quantum wells. The set of mixed strain quantum wells includes a set of compressive strained quantum wells and a set of tensile strained quantum wells. A potential difference applied across the SLED causes movement of electron carriers and hole carriers towards the active layer. Radiative recombination of electron and hole pairs in the set of compressive strained quantum wells enables emission of laterally polarized light and radiative recombination of electron and hole pairs in the set of tensile strained quantum wells enables emission of vertically polarized light. A combination of the laterally polarized light and vertically polarized light results in the emission of incoherent light from the SLED.

### CROSS REFERENCE TO RELATED APPLICATIONS

This application claims priority benefit of U.S. Provisional Application No. U.S. 63/112,905 filed in the U.S. Patent Office on Nov. 12, 2020, U.S. Provisional Application No. U.S. 63/169,192 filed in the U.S. Patent Office on Mar. 31, 2021, U.S. Provisional Application No. U.S. 63/173,764 filed in the U.S. Patent Office on Apr. 12, 2021, and U.S. Provisional Application No. U.S. 63/243,385 filed in the US Patent Office on Sep. 13, 2021. Each of the above-referenced applications is hereby incorporated herein by reference in its entirety.

### FIELD OF THE DISCLOSURE

Various embodiments of the disclosure relate generally to superluminescent light emitting diode (SLED). More particularly, various embodiments of the present disclosure relate to a mixed strain SLED.

### BACKGROUND

The light current characteristic of conventional superluminescent light emitting diode (SLED) is associated with increased optical power and is lower in the low-current regime. This represents a limitation for applications requiring SLEDs with high power in the low-current regime. In the light of the foregoing, there is a need for a technical solution that overcomes the abovementioned problems.

Limitations and disadvantages of conventional approaches will become apparent to one of skill in the art, through comparison of described systems with some aspects of the present disclosure, as outlined in the remainder of the present application and with reference to the drawings.

### SUMMARY

In an embodiment of the present disclosure, a superluminescent light emitting diode (SLED) is provided. The SLED comprises an n-type region, a p-type region, and an intrinsic region. The intrinsic region comprises an active layer sandwiched between two separate confinement heterostructure layers. The active layer has a set of mixed strain quantum wells (MQW) comprising a set of tensile strained quantum wells and a set of compressive strained quantum wells. The SLED is configured to emit incoherent light. An application of potential difference across an n-type region and a p-type region of the SLED results in movement of electron carriers and hole carriers towards the active layer, where radiative recombination of electron and hole pair in each compressive strained quantum well leads to emission of laterally polarized light and radiative recombination of electron and hole pair in each tensile strained quantum well leads to emission of vertically polarized light.

In some embodiments, a number of tensile strained quantum wells in the set of tensile strained quantum wells matches a number of compressive strained quantum wells in the set of compressive strained quantum wells.

In some embodiments, a compressive strain of the set of compressive strained quantum wells and a tensile strain of the set of tensile strained quantum wells is in a range of 0.7 to 1% of a total strain of the set of compressive strained quantum wells and the set of tensile strained quantum wells.

In some embodiments, a percentage difference between compressive strain of the set of compressive strained quantum wells and tensile strain of the set of tensile strained quantum wells is lower than 0.1%.

In some embodiments, a number of tensile strained quantum wells in the set of tensile strained quantum wells and compressive strained quantum wells in the set of compressive strained quantum wells is between 6 to 10.

In some embodiments, a thickness of each barrier layer of the plurality of barrier layers is in a range of 5 to 5.5 nanometers.

In some embodiments, a thickness of each of the tensile strained quantum well of the set of tensile strained quantum wells and the compressive strained quantum well of the set of compressive strained quantum wells is 7.5 nanometers.

In some embodiments, a polarization extinction coefficient of the SLED is less than 1 decibel.

In some embodiments, the SLED further comprises a first Separate Confinement Heterostructure (SCH) layer and a second SCH layer. The active layer is sandwiched between the first SCH layer and the second SCH layer.

In some embodiments, the SLED further comprises a substrate, a buffer layer, an n-contact waveguide grating layer, and a graded index layer. The first plurality of layers are formed on top of the substrate. The first plurality of layers comprise a buffer layer formed on the substrate, the n-contact waveguide grating layer formed on the buffer layer, and the graded index layer formed on the n-contact waveguide grating layer. The first SCH layer is formed on the graded index layer.

In some embodiments, the SLED further comprises an n-type metal layer formed below the substrate. The n-type metal layer includes a light-absorbing layer.

In some embodiments, the SLED further comprises a second plurality of layers. The second plurality of layers are formed on the second SCH layer. The second plurality of layers comprise a graded index layer, a p-contact waveguide grating layer, a p-contact layer, and a p-type metal layer. The graded index layer is formed on the second SCH layer. The p-contact waveguide grating layer is formed on the graded index layer. The p-contact layer is formed on the p-contact waveguide grating layer. The p-type metal layer is formed on the p-contact layer.

In some embodiments, the radiative recombination in the active layer is based on an application of a potential difference across the p-type metal layer and the n-type metal layer.

In some embodiments, the p-type metal layer and the p-contact layer form a p-cladding layer. Further, the p-cladding layer has a ridge geometry.

In some embodiments, a thickness of the first barrier layer and the second barrier layer is in a range of 10 to 14 nanometers.

In some embodiments, an operating current of the SLED is in a range of 100-200 milli-Amperes.

In some embodiments, a compressive strain and a tensile strain is 1.05% and 0.9% of a total strain of the set of compressive strained quantum wells and the set of tensile strained quantum wells.

In some embodiments, an increase in compressive strain of the set of compressive strained quantum wells increases tensile strain of the set of tensile strained quantum wells.

In some embodiments, a thickness of the first barrier layer is 5 nanometers.

In some embodiments, a thickness of the second barrier layer is 14 nanometers.

In various embodiments of the present disclosure, a superluminescent light emitting diode (SLED) is provided. The SLED comprises a first plurality of layers and an active layer grown on the first plurality of layers. The active layer comprises a plurality of barrier layers and a mixed strain multi-quantum well structure. The plurality of barrier layers comprises a first barrier layer and a second barrier layer. The mixed strain multi-quantum well structure comprises a set of tensile strained quantum wells and a set of compressive strained quantum wells. Each pair of quantum wells of the mixed strain multi-quantum well structure includes a tensile strained quantum well of the set of tensile strained quantum wells and a compressive strained quantum well of the set of compressive strained quantum wells. The first barrier layer of the plurality of barrier layers is sandwiched between a consecutive pair of quantum wells of the mixed strain multi-quantum well structure, and the second barrier layer is sandwiched between the tensile strained quantum well and the compressive strained quantum well of each pair of quantum wells of the mixed strain multi-quantum well structure. Based on radiative recombination in the active layer, the set of compressive strained quantum wells is configured to emit light with a laterally polarized orientation and the set of tensile strained quantum wells is configured to emit light with a vertically polarized orientation such that the SLED is configured to emit incoherent light.

The SLED of the present disclosure can be configured to operate at low current, have a broad bandwidth, and emit incoherent light with a low degree of polarization as compared to conventional SLEDs.

### BRIEF DESCRIPTION OF THE DRAWINGS

The accompanying drawings illustrate various embodiments of systems, methods, and other aspects of the disclosure. It will be apparent to a person skilled in the art that the illustrated element boundaries (e.g., boxes, groups of boxes, or other shapes) in the figures represent one example of the boundaries. In some examples, one element may be designed as multiple elements, or multiple elements may be designed as one element. In some examples, an element shown as an internal component of one element may be implemented as an external component in another and vice versa.

Various embodiments of the present disclosure are illustrated by way of example, and not limited by the appended figures, in which like references indicate similar elements, and in which:

FIG. 1 is a schematic diagram that illustrates a superluminescent light emitting diode (SLED), in accordance with an embodiment of the present disclosure;

FIG. 2 is a schematic diagram that illustrates a structure of an active layer of the SLED of FIG. 1, in accordance with an embodiment of the present disclosure;

FIG. 3 is a schematic diagram that illustrates a scanning electron micrograph of a type of the SLED of FIG. 1, in accordance with an embodiment of the present disclosure.

FIG. 4 is a schematic diagram that illustrates a scanning electron micrograph of another type of the SLED of FIG. 1 with improved topological characteristics, in accordance with an embodiment of the present disclosure;

FIG. 5 is a graph that illustrates a comparison of light-current (LI) characteristics between a conventional SLED and another type of the SLED of FIG. 1, in accordance with an embodiment of the present disclosure;

FIG. 6 is a graph that illustrates a comparison of light-current (LI) characteristics between different types of the SLED of FIG. 1, in accordance with an embodiment of the present disclosure;

FIG. 7 is a graph that illustrates horizontal and vertical far-field performance for a type of the SLED of FIG. 1, in accordance with an embodiment of the present disclosure; and

FIG. 8 is a graph that illustrates horizontal and vertical far-field performance of a type of the SLED of FIG. 1 that has a light-absorbing layer in an n-type metal layer of the SLED of FIG. 1, in accordance with an embodiment of the present disclosure.

Further areas of applicability of the present disclosure will become apparent from the detailed description provided hereinafter. It should be understood that the detailed description of exemplary embodiments is intended for illustration purposes only and is, therefore, not intended to necessarily limit the scope of the present disclosure.

### DETAILED DESCRIPTION

The present disclosure is best understood with reference to the detailed figures and description set forth herein. Various embodiments are discussed below with reference to the figures. However, those skilled in the art will readily appreciate that the detailed descriptions given herein with respect to the figures are simply for explanatory purposes as the methods and systems may extend beyond the described embodiments. In one example, the teachings presented and the needs of a particular application may yield multiple alternate and suitable approaches to implement the functionality of any detail described herein. Therefore, any approach may extend beyond the particular implementation choices in the following embodiments that are described and shown.

A “semiconductor” as used herein and throughout this disclosure refers to but is not limited to, a material having an electrical conductivity value falling between that of a conductor and an insulator. The material may be an elemental material or a compound material. A semiconductor may include, but not be limited to, an element, a binary alloy, a tertiary alloy, and a quaternary alloy. Structures formed using a semiconductor or semiconductors may comprise a single semiconductor material, two or more semiconductor materials, a semiconductor alloy of a single composition, a semiconductor alloy of two or more discrete compositions, and a semiconductor alloy graded from a first semiconductor alloy to a second semiconductor alloy. A semiconductor may be one of undoped (intrinsic), p-type doped, n-type doped, graded in doping from a first doping level of one type to a second doping level of the same type, and graded in doping from a first doping level of one type to a second doping level of a different type. Semiconductors may include but are not limited to III-V semiconductors, such as those between aluminum (Al), gallium (Ga), and indium (In) with arsenic (As), and tin (Sb), including for example Ga Nitride (N), GaP, GaAs, In Phosphide (P), InAs, AN and AlAs.

A “substrate” as used herein and throughout this disclosure refers to but is not limited to, a surface upon which semiconductor structures, such as an active layer and embodiments of the disclosure may be formed. This may include, but not be limited to, InP, GaAs, silicon, silica-on-silicon, silica, silica-on-polymer, glass, a metal, a ceramic, a polymer, or a combination thereof.

A “metal” as used herein and throughout this disclosure refers to but is not limited to, a material (element, compound, and alloy) that has good electrical and thermal conductivity as a result of readily losing outer shell electrons. This may include, but not be limited to, gold, chromium, aluminum, silver, platinum, nickel, copper, rhodium, palladium, tungsten, and combinations of such materials.

An “electrode”, “contact”, “track”, “trace”, or “terminal” as used herein and throughout this disclosure refers to but is not limited to, a material having good electrical conductivity and that is optically opaque. This includes structures formed from thin films, thick films, and plated films for example of materials including, but not limited to, metals such as gold, chromium, aluminum, silver, platinum, nickel, copper, rhodium, palladium, tungsten, and combinations of such materials. Other electrode configurations may employ combinations of metals, for example, a chromium adhesion layer and a gold electrode layer.

Tensile strained quantum well as used herein and throughout this disclosure refers to, but is not limited to, a quantum well in which a lattice constant of the quantum well is smaller than a lattice constant of an underlying layer which causes the lattice constant of the quantum well to stretch.

Compressive strained quantum well as used herein and throughout this disclosure refers to but is not limited to, a quantum well in which a lattice constant of quantum well is larger than a lattice constant of an underlying layer which causes the lattice constant of the quantum well to compress.

Polarization extinction coefficient or polarization extinction ratio as used herein and throughout this disclosure refers to but is not limited to, a coefficient or a ratio that gives a measure of the degree of polarization in decibel.

Optical gain as used herein and throughout this disclosure refers to but is not limited to, energy or power transmitted by an optical medium (such as an active layer of the disclosure) to an optical light that is traveling through the optical medium.

Amplified spontaneous emission gain as used herein and throughout this disclosure refers to but is not limited to, a gain that is a result of a process in which spontaneously emitted light is amplified by stimulated emission in the optical medium.

Light with a laterally polarized orientation as used herein and throughout this disclosure refers to but is not limited to, a light that vibrates along a direction of a transverse electric field (TE).

Light with a vertically polarized orientation as used herein and throughout this disclosure refers to but is not limited to, a light that vibrates along a direction of a transverse magnetic field (TM).

Incoherent light as used herein and throughout this disclosure refers to but is not limited to, light in which photons have different frequencies and different phases with respect to each other.

Radiative recombination as used herein and throughout this disclosure refers to but is not limited to, a process in which recombination of an electron and a hole leads to emission of a photon.

Separate confinement heterostructure (SCH) layers as used herein and throughout this disclosure refers to, but are not limited to, a pair of layers that sandwich quantum well layers of an active layer. The SCH layers have a lower refractive index than the quantum well layers and provide vertical optical confinement to the SLED device. The material of the SCH layers may include, but is not limited to, undoped indium gallium arsenide phosphide (InGaAsP), undoped indium aluminum gallium arsenide (InAlGaAs), and undoped InGaAs.

References to “an embodiment”, “another embodiment”, “yet another embodiment”, “one example”, “another example”, “yet another example”, “for example” and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in an embodiment” does not necessarily refer to the same embodiment.

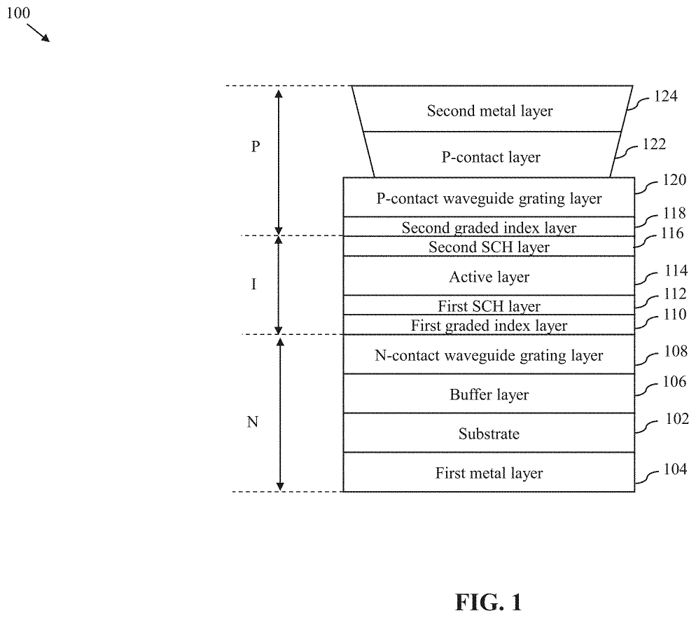

Referring now to FIG. 1, a superluminescent light emitting diode (SLED) 100 in accordance with an embodiment of the present disclosure is shown. The SLED 100 is a semiconductor light source that emits optical light which is incoherent. The SLED 100 may be employed in various optical systems of fiber optic gyroscope, navigation systems, and gas sensors. The SLED 100 includes a substrate 102 and a first plurality of layers formed sequentially on top of a substrate 102. Forming of the first plurality of layers herein may refer to depositing and/or growing the first plurality of layers. A first metal layer 104 is formed below the substrate 102 and configured as a cathode terminal. In an embodiment, the first metal layer 104 is an n-type metal layer 104. The n-type metal layer 104, i.e., the first metal layer 104, includes a light-absorbing layer.

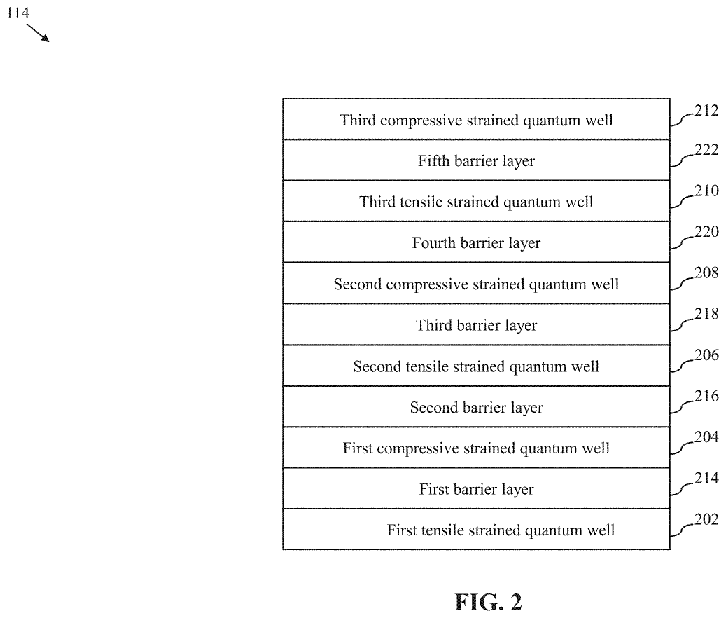

The first plurality of layers include a buffer layer 106, an n-contact waveguide grating layer 108, and a first graded index layer 110. The SLED 100 further includes a first separate confinement heterostructure (SCH) layer 112, an active layer 114, a second SCH layer 116, and a second plurality of layers. The second plurality of layers are formed on the second SCH layer 116. The second plurality of layers include a second graded index layer 118, a p-contact waveguide grating layer 120, a p-contact layer 122, and a second metal layer 124. In an embodiment, the second metal layer 124 is a p-type metal layer 124. The structure of the active layer 114 includes a mixed set of compressive and tensile strained individual quantum wells as explained in detail in FIG. 2. The mixed set of compressive and tensile strained individual quantum wells emit opposing polarized light that is balanced by the compressive and tensile strained quantum wells and results in the SLED 100 emitting incoherent light. Thus, the SLED 100 is a mixed strain SLED 100.

The buffer layer 106 is formed on top of the substrate 102 using suitable film deposition techniques that include but are not limited to physical vapor deposition (PVD) such as thermal evaporation, electron beam evaporation, and sputter deposition, and chemical vapor deposition (CVD) such as metal-organic CVD, laser CVD, and plasma-enhanced CVD. The buffer layer 106 is manufactured using oxides of suitable metals such as Zinc (Zn), Titanium (Ti), Tungsten (W), Niobium (Ni), or a suitable combination thereof.

The n-contact waveguide grating layer 108 is formed on the buffer layer 106 using suitable film deposition techniques as stated in reference to the buffer layer 106. The n-contact waveguide grating layer 108 may include one waveguide layer and/or one grating layer. The n-contact waveguide grating layer 108 is formed from suitably doped n-type material such as phosphorous, arsenic, or any combination thereof. The n-contact waveguide grating layer 108 passes light of a corresponding wavelength and blocks light of other wavelengths.

The first graded index layer 110 is formed on the n-contact waveguide grating layer 108. The first graded index layer 110 may be formed from a transparent dielectric such as silicon oxide or a mixture of dielectric materials that has a higher index of refraction than silicon oxide such as niobium oxide, tantalum oxide, titanium oxide, other metal oxides, oxynitrides, silicon nitride, or a suitable combination thereof. The first graded index layer 110 prevents the scattering of light that is emitted by the SLED 100. The first graded index layer 110 has a lower refractive index as compared to the n-contact waveguide grating layer 108.

The first SCH layer 112 is formed on the first graded index layer 110. The active layer 114 is grown on the first plurality of layers. In other words, the active layer 114 is formed on the first SCH layer 112. The second SCH layer 116 is formed on the active layer 114. Thus, the active layer 114 is sandwiched between the first SCH layer 112 and the second SCH layer 116. The first SCH layer 112 and the second SCH layer 116 have a lower refractive index as compared to the active layer 114 and provide vertical optical confinement to the optical light emitted from the SLED 100.

The second plurality of layers are formed on the second SCH layer 116. The second plurality of layers includes a second graded index layer 118, a p-contact waveguide grating layer 120, a p-contact layer 122, and a second metal layer 124. In an embodiment, the second metal layer 124 is a p-type metal layer 124. The second metal layer 124 and the p-contact layer 122 form a p-cladding layer such that the p-cladding layer has a ridge geometry. The ridge geometry shapes a current spreading profile of current flowing in the SLED 100 into a funnel shape, thus limiting a current leakage in the SLED 100.

The second graded index layer 118 is formed on the second SCH layer 116. The material and the method of forming the second graded index layer 118 is similar to the material and the method of forming the first graded index layer 110. The second graded index layer 118 reduces the scattering of light emitted in the active layer 114. The second graded index layer 118 has a lower refractive index with respect to the second SCH layer 116.

The p-contact waveguide grating layer 120 is formed on the second SCH layer 116 using suitable film deposition techniques as stated above. The p-contact waveguide grating layer 120 may include one waveguide layer and/or one grating layer. The p-contact waveguide grating layer 120 is formed from suitably doped p-type material such as aluminum, boron, or any combination thereof. The p-contact waveguide grating layer 120 passes light of a corresponding wavelength and blocks the light of other wavelengths.

The p-contact layer 122 is formed on the p-contact waveguide grating layer 120. The p-contact layer 122 provides hole carriers that travel towards the active layer 114 to recombine with electron carriers. The second metal layer 124 is formed on the p-contact layer 122. The second metal layer 124, the p-contact layer 122, the p-contact waveguide grating layer 120, and the second graded index layer 118 form a p-type region (shown as ‘P’ in FIG. 1) of the SLED 100. The second metal layer 124 is configured as an anode terminal to apply a potential difference across the SLED 100.

The first graded index layer 110, the n-contact waveguide grating layer 108, the buffer layer 106, the substrate 102, and the first metal layer 104 form an n-type region (shown as ‘N’ in FIG. 1) of the SLED 100. The second SCH layer 116, the active layer 114, and the first SCH layer 112 form an intrinsic region (shown as T in FIG. 1) of the SLED 100. The intrinsic region of the SLED 100 has a lower electrical conductivity with respect to the p-type region and the n-type region of the SLED 100. The intrinsic region of the SLED 100 is an undoped region of the SLED 100.

In operation, when a potential difference is applied across the first metal layer 104 and the second metal layer 124, hole carriers flow from the p-type region of the SLED 100, and electron carriers flow from the n-type region of the SLED 100 to the intrinsic region of the SLED 100. The incoherent light generation occurs in the active layer 114 based on electron-hole recombination in the active layer 114, i.e., radiative recombination is induced in the active layer 114 due to injected electron and hole carriers. The first SCH layer 112 and the second SCH layer 116 serve as dopant setback layers and regulators of the incoherent light in the vertical emission direction of the SLED 100. Thus, the undoped first SCH layer 112 and the second SCH layer 116 provide vertical optical confinement to the incoherent light emitted by the process of radiative recombination in the active layer 114 of the SLED 100.

Referring now to FIG. 2, a structure of the active layer 114 in accordance with an embodiment of the present disclosure is shown. The active layer 114 includes a mixed strain multi-quantum well structure 202, 204, 206, 208, 210, and 212 and a plurality of barrier layers 214, 216, 218, 220, and 222. The mixed strain multi-quantum well structure 202, 204, 206, 208, 210, and 212 includes a set of tensile strained quantum wells 202, 206, and 210 and a set of compressive strained quantum wells 204, 208, and 212. The set of tensile strained quantum wells 202, 206, and 210 includes a first tensile strained quantum well 202, a second tensile strained quantum well 206, and a third tensile strained quantum well 210. The set of compressive strained quantum wells 204, 208, and 212 includes a first compressive strained quantum well 204, a second compressive strained quantum well 208, and a third compressive strained quantum well 212. A number of tensile strained quantum wells in the set of tensile strained quantum wells 202, 206, and 210 matches a number of compressive strained quantum wells in the set of compressive strained quantum wells 204, 208, and 212. Further, a number of tensile strained quantum wells in the set of tensile strained quantum wells 202, 206, and 210 and compressive strained quantum wells in the set of compressive strained quantum wells 204, 208, and 212 is between 6 to 10.

The first tensile strained quantum well 202 and the first compressive strained quantum well 204 form a first pair of quantum wells 202 and 204 of the mixed strain multi-quantum well structure 202, 204, 206, 208, 210, and 212. The second tensile strained quantum well 206 and the second compressive strained quantum well 208 form a second pair of quantum wells 206 and 208 of the mixed strain multi-quantum well structure 202, 204, 206, 208, 210, and 212. Similarly, the third tensile strained quantum well 210 and the third compressive strained quantum well 212 form a third pair of quantum wells 210 and 212 of the mixed strain multi-quantum well structure 202, 204, 206, 208, 210, and 212. Thus, the first pair of quantum wells 202 and 204, the second pair of quantum wells 206 and 208, and the third pair of quantum wells 210 and 212 are consecutive pairs of quantum wells.

The plurality of barrier layers 214, 216, 218, 220, and 222 include a first barrier layer 214, a second barrier layer 216, a third barrier layer 218, a fourth barrier layer 220, and a fifth barrier layer 222. A barrier layer of the plurality of barrier layers 214, 216, 218, 220, and 222 is sandwiched between a consecutive pair of quantum wells of the mixed strain multi-quantum well structure 202, 204, 206, 208, 210, and 212. Thus, the second barrier layer 216 is sandwiched between the first pair of quantum wells 202 and 204 and the second pair of quantum wells 206 and 208. Further, the fourth barrier layer 220 is sandwiched between the second pair of quantum wells 206 and 208 and the third pair of quantum wells 210 and 212.

Another barrier layer is sandwiched between the tensile strained quantum well and the compressive strained quantum well of each pair of quantum wells of the mixed strain multi-quantum well structure 202, 204, 206, 208, 210, and 212. Thus, the first barrier layer 214 is sandwiched between the first tensile strained quantum well 202 and the first compressive strained quantum well 204. The third barrier layer 218 is sandwiched between the second tensile strained quantum well 206 and the second compressive strained quantum well 208. Further, the fifth barrier layer 222 is sandwiched between the third tensile strained quantum well 210 and the third compressive strained quantum well 212.

Based on radiative recombination in the active layer 114, the set of compressive strained quantum wells 204, 208, and 212 is configured to emit light with a laterally polarized orientation, and the set of tensile strained quantum wells 202, 206, and 210 is configured to emit light with a vertically polarized orientation. The SLED 100 is thus configured to emit the incoherent light due to the combination of the laterally polarized light and the vertically polarized light.

The set of compressive strained quantum wells 204, 208, and 212 and the set of tensile strained quantum wells 202, 206, and 210 are grown by metal-organic chemical vapor deposition (MOCVD) technique where the tailoring of the InxGa1-xAsyP1-y stoichiometry results in the growth of the set of compressive strained quantum wells 204, 208, and 212 and the set of tensile strained quantum wells 202, 206, and 210. Precursor gases of suitable materials set at predefined power levels are used for growing a compressive strained quantum well and a tensile strained quantum well using MOCVD as will be understood by a person skilled in the art. The ‘x’ and ‘y’ can be varied during the epitaxial growth of the SLED 100, according to a ratio of the gases used during the growth which result in different compositions for the compressive and tensile strained quantum wells. During the formation of the compressive strained quantum well, a strain applied to the quantum well results in having a different lattice constant of the quantum well than the underlying barrier layer. Compressive strain is used for compositions where an epitaxial unit-cell of the quantum well is greater than a lattice-matched unit-cell. In an example, the first compressive strained quantum well 204 has a higher lattice constant than the first barrier layer 214. Similarly, the remaining compressive strained quantum wells are grown in a manner similar to the formation of the first compressive strained quantum well 204.

During the formation of the tensile strained quantum well, a strain applied to the quantum well results in a different lattice constant of the quantum well than the underlying layer. Tensile strain is used for compositions where the unit-cell of the tensile strained quantum well is smaller than the lattice-matched unit-cell of the underlying layer. In an example, the second tensile strained quantum well 206 has a smaller lattice constant than the second barrier layer 216. Similarly, the remaining tensile strained quantum wells are grown in a manner similar to the formation of the second tensile strained quantum well 206. In other embodiments, the set of compressive strained quantum wells 204, 208, and 212 and the set of tensile strained quantum wells 202, 206, and 210 can be formed using other CVD processes, PVD processes, Atomic layer deposition (ALD) processes, other suitable thin film deposition processes, or a suitable combination thereof.

Barrier layers separate each of the compressive and tensile strained quantum wells. A thin barrier layer facilitates a valence band mixing between a compressive strained quantum well and a tensile strained quantum well, whereas a thick barrier layer between a compressive strained quantum well and a tensile strained quantum well improves an epitaxial quality of the active layer 114. Barrier layers have different compositions of materials in comparison to quantum wells and are used for facilitating the growth of strained quantum wells of the mixed strain multi-quantum well structure 202, 204, 206, 208, 210, and 212.

In an embodiment for a first type of the SLED 100, the compressive strain of the set of compressive strained quantum wells 204, 208, and 212 and the tensile strain of the set of tensile strained quantum wells 202, 206, and 210 is in a range of 0.7 to 1% of a total strain of the set of compressive strained quantum wells 204, 208, and 212 and the set of tensile strained quantum wells 202, 206, and 210. Further, a percentage difference between a compressive strain of the set of compressive strained quantum wells 204, 208, and 212 and tensile strain of the set of tensile strained quantum wells 202, 206, and 210 known as a net strain is lower than 0.1%, i.e., in a range of 0-0.1%. Experimental results show that the value of net strain greater than 0.1% results in degraded epitaxial quality of the active layer 114. In an example, the compressive strain is 0.7% of the total strain and the tensile strain is 0.7%-0.8% of the total strain. A thickness of each of the tensile strained quantum well of the set of tensile strained quantum wells 202, 206, and 210 and the compressive strained quantum well of the set of compressive strained quantum wells 204, 208, and 212 is 7.5 nanometers. Further, a thickness of each barrier layer of the plurality of barrier layers, i.e., the first through fifth barrier layers 214, 216, 218, 220, and 222 is in a range of 5 to 5.5 nanometers. A number of quantum wells of the set of tensile strained quantum wells 202, 206, and 210 and the set of compressive strained quantum wells 204, 208, and 212 are in a range of 6-10.

In another embodiment for a second type of the SLED 100, the compressive strain and the tensile strain is 1.05% and 0.9% of a total strain of the set of compressive strained quantum wells 204, 208, and 212 and the set of tensile strained quantum wells 202, 206, and 210, respectively. A thickness of each of the tensile strained quantum well of the set of tensile strained quantum wells 202, 206, and 210 and the compressive strained quantum well of the set of compressive strained quantum wells 204, 208, and 212 is 7.5 nanometers. The thickness of each barrier layer of the plurality of barrier layers, i.e., the first through fifth barrier layers 214, 216, 218, 220, and 222 is in a range of 10 to 14 nanometers. The number of quantum wells of the set of tensile strained quantum wells 202, 206, and 210 and the set of compressive strained quantum wells 204, 208, and 212 is 6 such that 3 tensile strained quantum wells and 3 compressive strained quantum wells are included in the mixed strain multi-quantum well structure 202, 204, 206, 208, 210, and 212.

In yet another embodiment for a third type of the SLED 100, the compressive strain and the tensile strain is 0.95% and 0.9% of a total strain of the set of compressive strained quantum wells 204, 208, and 212 and the set of tensile strained quantum wells 202, 206, and 210, respectively. A thickness of each of the tensile strained quantum well of the set of tensile strained quantum wells 202, 206, and 210 and the compressive strained quantum well of the set of compressive strained quantum wells 204, 208, and 212 is 8 nanometers. The thickness of each barrier layer of the plurality of barrier layers, i.e., the first through fifth barrier layers 214, 216, 218, 220, and 222 is 14 nanometers. Further, the compressive strain of the set of compressive strained quantum wells 204, 208, and 212 is increased from 0.95% to 1%. The number of quantum wells of the set of tensile strained quantum wells 202, 206, and 210 and the set of compressive strained quantum wells 204, 208, and 212 is 6 such that 3 tensile strained quantum wells and 3 compressive strained quantum wells are included in the mixed strain multi-quantum well structure 202, 204, 206, 208, 210, and 212.

In yet another embodiment for a dual barrier SLED 100, i.e., a fourth type of the SLED 100, the thickness of each barrier layer sandwiched between the tensile strained quantum well and the compressive strained quantum well of each pair of quantum wells, i.e., the first barrier layer 214, the third barrier layer 218, and the fifth barrier layer 222, is in a range of 5 to 5.5 nanometers. Further, the thickness of a barrier layer of the plurality of barrier layers 214, 216, 218, 220, and 222 that is sandwiched between a consecutive pair of quantum wells, such as the second barrier layer 216 and the fourth barrier layer 220, is in a range of 10 to 14 nanometers. The number of quantum wells of the set of tensile strained quantum wells 202, 206, and 210 and the set of compressive strained quantum wells 204, 208, and 212 is 6 such that 3 tensile strained quantum wells and 3 compressive strained quantum wells are included in the mixed strain multi-quantum well structure 202, 204, 206, 208, 210, and 212. The fourth type of the SLED 100 provides a thick barrier layer (10 to 14 nanometers) that aids in reducing defects (interfacial defects) at an interface that occur due to a lattice constant mismatch between a barrier layer and a quantum well whereas a thin barrier layer (5 to 5.5 nanometers) facilitates a valence band mixing between a compressive strained quantum well and a tensile strained quantum well.

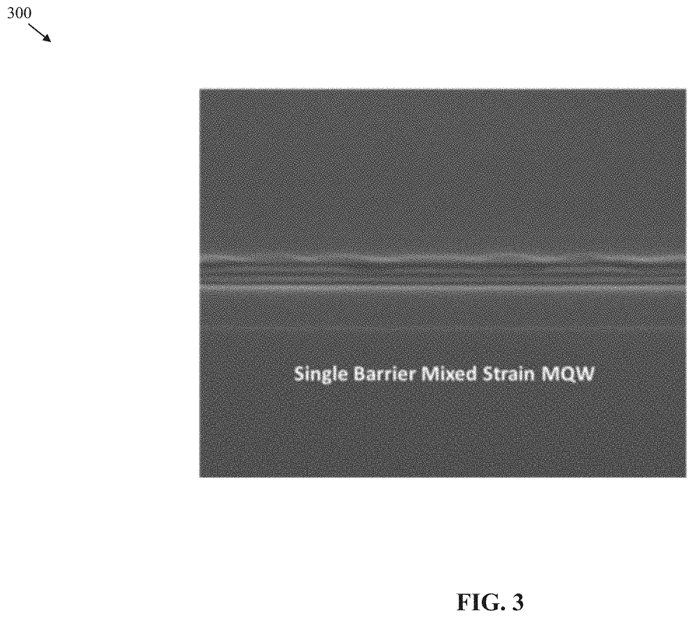

FIG. 3 is a schematic diagram 300 that illustrates a scanning electron micrograph of the first type of the SLED 100 (also referred to as a single barrier mixed strain multi-quantum well (MQW) SLED 100) in accordance with an embodiment of the present disclosure. The topmost barrier layer is thin (thickness ranging between 5 to 5.5 nanometers). The topmost barrier layer may take the form of wavy surface morphology as seen in FIG. 3.

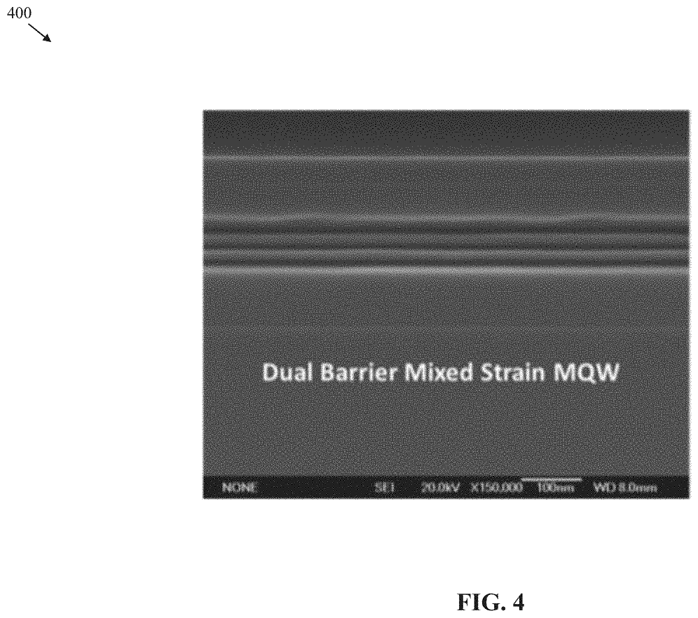

FIG. 4 is a schematic diagram 400 that illustrates a scanning electron micrograph of the fourth type of the SLED 100 (also referred to as a dual barrier mixed strain MQW SLED 100) with improved topological characteristics in accordance with an embodiment of the present disclosure. The thickness of each of the first barrier layer 214, the third barrier layer 218, and the fifth barrier layer 222 is 5 nanometers to facilitate valence-band mixing between a tensile strained quantum well and a compressive strained quantum well of the same pair of quantum wells which leads to a low degree of polarization of the emitted light. Further, the thickness of each of the second barrier layer 216 and the fourth barrier layer 220 is 14 nanometers which results in improved topological characteristics of the active layer 114 as compared to the first type of the SLED 100.

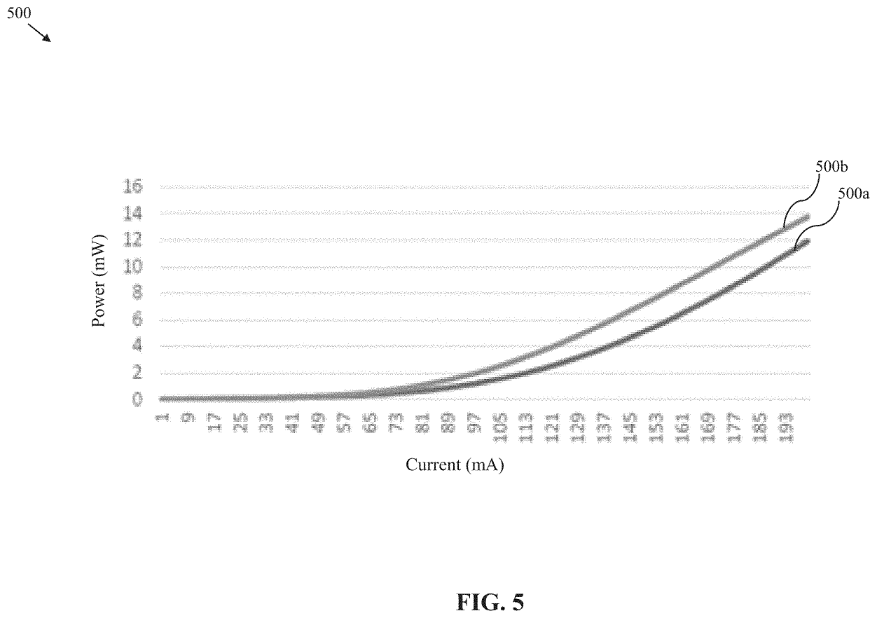

FIG. 5 is a graph 500 that illustrates a comparison of light-current (LI) characteristics between a conventional SLED and the second type of the SLED 100, in accordance with an embodiment of the present disclosure. The Y-axis represents power in milliWatts (0-16 mW) of the emitted optical light by both the conventional SLED and the second type of the SLED 100 whereas X-axis represents an operating current in milliAmperes (1-193 mA) for both the conventional SLED and the second type of the SLED 100. In FIG. 5, curve 500a represents the LI characteristics of the conventional SLED while curve 500b represents the LI characteristics of the second type of the SLED 100. In the conventional SLED, an active layer includes only a set of compressive strained quantum wells separated by barrier layers. In the conventional SLED, the number of quantum wells is 7 and the compressive strain is 1.05% of the total strain. The second type of the SLED 100 of the present disclosure includes 6 quantum wells and further includes three 0.9% tensile strained quantum wells in addition to the other three compressive strained quantum wells. Higher optical power in the low-current regime is obtained by the second type of the SLED 100 with respect to the conventional SLED due to the mixed strain multi-quantum well structure 202, 204, 206, 208, 210, and 212 as seen in the LI characteristics of curve 500b in comparison with the LI characteristics of curve 500a, respectively.

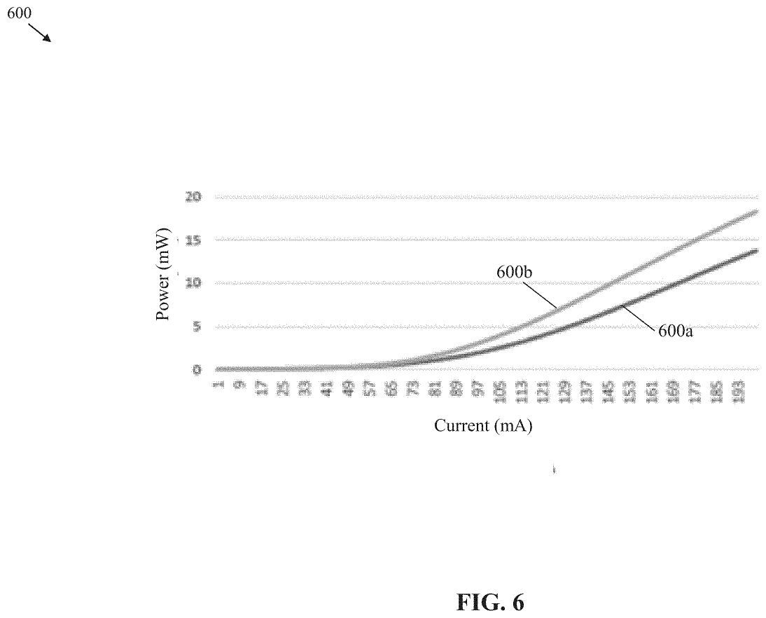

FIG. 6 is a graph 600 that illustrates a comparison of light-current (LI) characteristics between the first type of the SLED 100 and the third type of the SLED 100, in accordance with an embodiment of the present disclosure. The Y-axis represents power (in 0-20 mW) of the emitted optical light by both the first type of the SLED 100 and the third type of the SLED 100 whereas X-axis represents an operating current (in 1-193 mA) in both the first type of the SLED 100 and the third type of the SLED 100. The third type of the SLED 100 includes 6 alternating quantum wells. The third type of the SLED 100 is a strain modulated SLED 100. The 6 alternating quantum wells include 3 compressive strained quantum wells and 3 tensile strained quantum wells. The thickness of each quantum well is 8 nanometers, the thickness of each of the first through fifth barrier layers 214, 216, 218, 220, and 222 is 14 nanometers, the tensile strained quantum wells have a strain of 0.9%, and the compressive strained quantum wells have a strain of 0.95%.

As understood by a person skilled in the art, to achieve increased Amplified Spontaneous Emission (ASE) gain from a tensile strained quantum well, the tensile strain of the quantum well needs to be increased. However, this may result in epitaxial defects which in turn lower the ASE gain. The third type of the SLED 100 offers an alternative approach to increase the tensile ASE gain from the SLED 100. When the strain on a compressive strained quantum well is increased, an additional strain on the tensile strained quantum well is exerted on the same pair of quantum wells. In an example, the strain on the first tensile strained quantum well 202 is increased by increasing the strain on the first compressive strained quantum well 204. Similarly, the strain on the remaining tensile strained quantum wells is increased by increasing the corresponding strain on the compressive strained quantum wells of the corresponding pair of quantum wells. As seen in graph 600, the power increases significantly when the strain on the compressive strained quantum wells is increased from 0.95% (power represented by curve 600a) to 1.0% (power represented by curve 600b).

The Polarization Extinction Ratio (PER) depends upon the transverse electric field (TE) and transverse magnetic field (TM) of a non-strain modulated mixed-strain SLED 100, i.e., the first type of the SLED 100. The first type of the SLED 100 has PER of 8 decibels (dB) with a dominant TM mode due to an equal number of tensile and compressive strained quantum wells and high optical gain associated with each tensile strained quantum well. Conventionally, the PER decreases with an increase in TE mode intensity that is contributed by the higher strain of compressive strained quantum wells. However, in the third type of the SLED 100, the PER increases from 8 to ˜10-12 dB with an increase in the dominant TM mode.

As understood by a person skilled in the art, the TM mode intensity gain increases with an increase in the tensile strain optical gain. An increase in the compressive strain of a compressive strained quantum well results in an increase in the tensile strain of a corresponding tensile strained quantum well in the same pair of quantum wells that further leads to increase in tensile strain optical gain and the TM mode intensity gain. Further, the increase in the compressive strained quantum wells increases the super-linear characteristics of the third type of the SLED 100 with respect to the first type of the SLED 100.

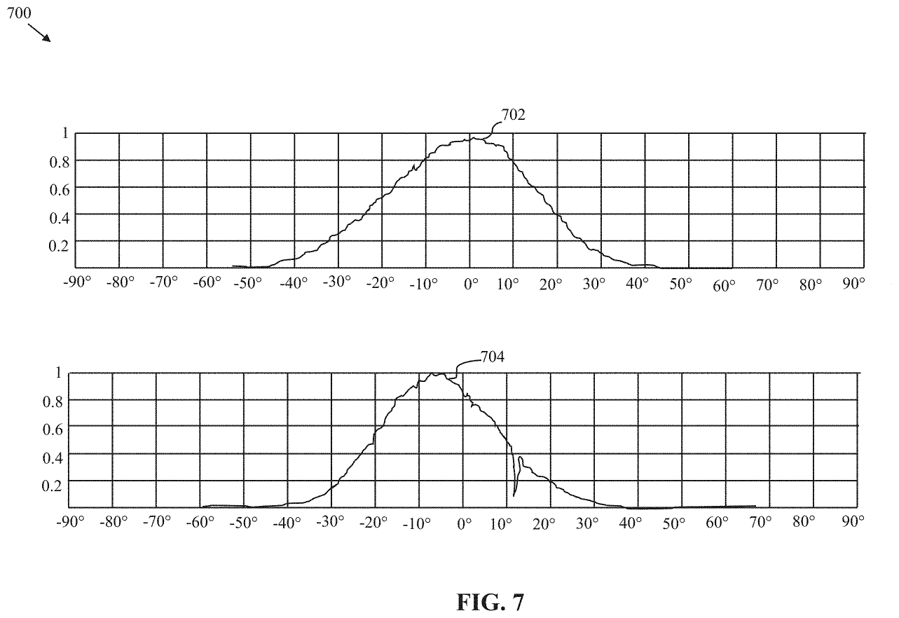

FIG. 7 is a graph 700 that illustrates horizontal 702 and vertical 704 far-field performance for the first type of the SLED 100 in accordance with an embodiment of the present disclosure. X-axis represents the far-field angle in θ (−90 degrees to 90 degrees) whereas Y-axis represents normalized intensity (0.2 to 1 arbitrary unit (au)). The horizontal far-field performance refers to full-width at half maximum of the optical output power intensity of the SLED 100 when measured along the X-axis. The vertical far-field performance refers to full-width at half maximum of the optical output power intensity of the SLED 100 when measured along the Y-axis. The incorporation of the first type of the SLED 100 which emits incoherent light with a low degree of polarization into optical systems requires an optical output of the first type of the SLED 100 to be coupled into an optical fiber (not shown). Coupling efficiencies up to 45% of total optical output may be achieved by coupling the SLED 100 to a single-mode optical fiber.

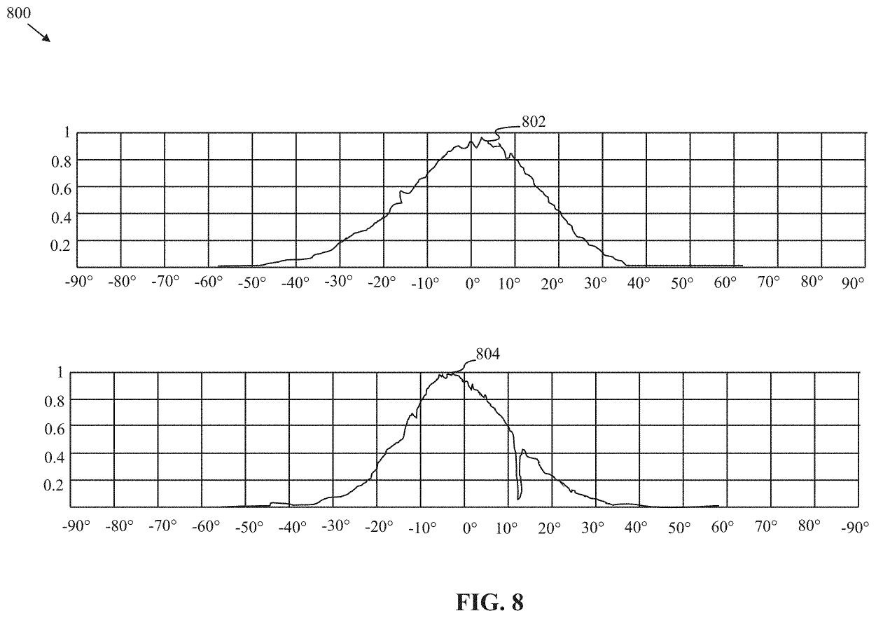

FIG. 8 is a graph 800 that illustrates the horizontal 802 and vertical 804 far-field performance of the first type of the SLED 100 that has a light-absorbing layer in the n-type metal layer 104, in accordance with an embodiment of the present disclosure. In an embodiment, the light-absorbing layer is an indium gallium arsenide phosphide (InGaAsP) layer. X-axis represents the far-field angle in θ (−90 degrees to 90 degrees) whereas Y-axis represents normalized intensity (0.2 to 1 au). The horizontal far-field performance refers to full-width at half maximum of the optical output power intensity of the SLED 100 when measured along the X-axis. The vertical far-field performance refers to full-width at half maximum of the optical output power intensity of the SLED 100 when measured along the Y-axis. For obtaining a more circular far-field performance, the thickness of the first SCH layer 112 is reduced in the first type of the SLED 100 to allow an optical mode of the incoherent light to expand. As a result, the shape of the optical mode changes from an elliptical shape to a circular shape. A circular optical mode increases the coupling efficiency of the optical mode into the optical fiber.

Thus, the SLED 100 having a mixed strain multi-quantum well structure 202, 204, 206, 208, 210, and 212 manufactured by the method as explained above, results in the emission of incoherent light with reduced epitaxial defects in the active layer 114 of the SLED 100 and improved coupling efficiency for coupling the SLED 100 to an optical fiber. Further, the first type of the SLED 100 and the fourth type of the SLED 100 emit incoherent light with a very low degree of polarization (for example the PER is less than 1 dB, i.e., in the range of 0-1 dB. The second type of the SLED 100 and the third type of the SLED 100 emit light at high power and operate at low operating current (example 100-200 mA). Further, the emitted incoherent light is in a broad bandwidth range.

Techniques consistent with the present disclosure provide, among other features, a mixed strain multi quantum well SLED 100. While various exemplary embodiments of the disclosed system and method have been described above it should be understood that they have been presented for purposes of example only, not limitations. It is not exhaustive and does not limit the disclosure to the precise form disclosed.

In the claims, the words ‘comprising’, ‘including’, and ‘having’ does not exclude the presence of other elements or steps than those listed in a claim. The terms “a” or “an,” as used herein, are defined as one or more than one. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

While various embodiments of the present disclosure have been illustrated and described, it will be clear that the present disclosure is not limited to these embodiments only. Numerous modifications, changes, variations, substitutions, and equivalents will be apparent to those skilled in the art, without departing from the spirit and scope of the present disclosure, as described in the claims.

1. A superluminescent light emitting diode (SLED), comprising:
a first plurality of layers; and
an active layer grown on the first plurality of layers, the active layer comprising:
a plurality of barrier layers comprising a first barrier layer and a second barrier layer; and
a mixed strain multi-quantum well structure comprising a set of tensile strained quantum wells and a set of compressive strained quantum wells, wherein each pair of quantum wells of the mixed strain multi-quantum well structure includes a tensile strained quantum well of the set of tensile strained quantum wells and a compressive strained quantum well of the set of compressive strained quantum wells, wherein the first barrier layer of the plurality of barrier layers is sandwiched between a consecutive pair of quantum wells of the mixed strain multi-quantum well structure, and the second barrier layer is sandwiched between the tensile strained quantum well and the compressive strained quantum well of each pair of quantum wells of the mixed strain multi-quantum well structure, and wherein based on radiative recombination in the active layer, the set of compressive strained quantum wells is configured to emit light with a laterally polarized orientation and the set of tensile strained quantum wells is configured to emit light with a vertically polarized orientation such that the SLED is configured to emit incoherent light.

2. The SLED of claim 1, wherein a number of tensile strained quantum wells in the set of tensile strained quantum wells matches a number of compressive strained quantum wells in the set of compressive strained quantum wells.

3. The SLED of claim 1, wherein a compressive strain of the set of compressive strained quantum wells and a tensile strain of the set of tensile strained quantum wells is in a range of 0.7 to 1% of a total strain of the set of compressive strained quantum wells and the set of tensile strained quantum wells.

4. The SLED of claim 1, wherein a percentage difference between compressive strain of the set of compressive strained quantum wells and tensile strain of the set of tensile strained quantum wells is lower than 0.1%.

5. The SLED of claim 1, wherein a number of tensile strained quantum wells in the set of tensile strained quantum wells and compressive strained quantum wells in the set of compressive strained quantum wells is between 6 to 10.

6. The SLED of claim 1, wherein a thickness of each barrier layer of the plurality of barrier layers is in a range of 5 to 5.5 nanometers.

7. The SLED of claim 1, wherein a thickness of each of the tensile strained quantum well of the set of tensile strained quantum wells and each of the compressive strained quantum well of the set of compressive strained quantum wells is 7.5 nanometers.

8. The SLED of claim 1, wherein a polarization extinction coefficient of the SLED is less than 1 decibel.

9. The SLED of claim 1, further comprising a first Separate Confinement Heterostructure (SCH) layer and a second SCH layer, wherein the active layer is sandwiched between the first SCH layer and the second SCH layer.

10. The SLED of claim 9, further comprising:
a substrate, wherein the first plurality of layers are formed on top of the substrate, and wherein the first plurality of layers comprise:
a buffer layer formed on the substrate;
an n-contact waveguide grating layer formed on the buffer layer; and
a graded index layer formed on the n-contact waveguide grating layer, wherein the first SCH layer is formed on the graded index layer.

11. The SLED of claim 10, further comprising:
an n-type metal layer formed below the substrate, wherein the n-type metal layer includes a light-absorbing layer.

12. The SLED of claim 11, further comprising:
a second plurality of layers formed on the second SCH layer, wherein the second plurality of layers comprise:
a graded index layer formed on the second SCH layer;
a p-contact waveguide grating layer formed on the graded index layer;
a p-contact layer formed on the p-contact waveguide grating layer; and
a p-type metal layer formed on the p-contact layer.

13. The SLED of claim 12, wherein the radiative recombination in the active layer is based on an application of a potential difference across the p-type metal layer and the n-type metal layer.

14. The SLED of claim 12, wherein the p-type metal layer and the p-contact layer form a p-cladding layer, and wherein the p-cladding layer has a ridge geometry.

15. The SLED of claim 12, a thickness of each of the first barrier layer and the second barrier layer is in a range of 10 to 14 nanometers.

16. The SLED of claim 1, wherein an operating current of the SLED is in a range of 100-200 milli-Amperes.

17. The SLED of claim 16, wherein a compressive strain and a tensile strain is 1.05% and 0.9%, respectively, of a total strain of the set of compressive strained quantum wells and the set of tensile strained quantum wells.

18. The SLED of claim 1, wherein an increase in a compressive strain of the set of compressive strained quantum wells increases a tensile strain of the set of tensile strained quantum wells.

19. The SLED of claim 18, wherein a thickness of the first barrier layer is 5 nanometers.

20. The SLED of claim 18, wherein a thickness of the second barrier layer is 14 nanometers.
